(19) United States
(12) Patent Application Publication
(10) Pub. No.: US 2007/0105280 A1
(43) Pub. Date: May 10, 2007

(54) BRACE FOR WIRE LOOP

(75) Inventor: Zhe Li, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/557,754

(22) Filed: Nov. 8, 2006

(30) Foreign Application Priority Data
Nov. 9, 2005 (CN) 200510124613.7

(51) Int. Cl. H01L 23/495; H01L 21/00

(52) U.S. Cl. 438/123; 257/676; 257/E23.039

(57) ABSTRACT

A method of connecting a lead frame (12) lead finger (16a) to a bond pad (18a) on an integrated circuit (IC) die (10) includes bonding a first bonding wire (20a) from the lead finger (16a) to an intermediate point (22). A second bonding wire (20b) is bonded from the lead finger (16a) to the bond pad (18a) such that the first bonding wire (20a) supports the second bonding wire (20b).

### BACKGROUND OF THE INVENTION

The present invention relates to wire bonding in general and more specifically to a brace for a long wire loop.

Wire bonding typically involves connecting a bond pad on an integrated circuit (IC) die to a lead finger of a lead frame with a bonding wire. Referring to FIG. 1, a packaged semiconductor device 10 is shown. The device 10 includes an integrated circuit (IC) die 12 attached to a lead frame paddle 14 with an adhesive 16. Bond pads on the IC die 12 are electrically connected to lead frame fingers 18 with bond wires 20 and 22. The bond wire 20 is a typical bond wire in that it extends from a bond pad located on a periphery of the IC 12 to one of the lead fingers 18, whereas the bond wire 22 is a long wire because it extends from a bond pad located in a central area of the IC die 12 to one of the lead fingers 18. Thus, a bond pad may be located inboard, that is, away from a periphery of the IC die, or along the periphery of the IC die.

Bonding wires of a substantial length, like the bond wire 22, are often needed to connect the inboard bond pads to the lead frame lead fingers. Correspondingly, wire loops of a significant length are usually formed between the inboard bond pads and the lead frame lead fingers. To prevent wire-to-die shorting, a height clearance of at least two (2) times the diameter of the bonding wire must be maintained over the surface of the IC die. However, creating a wire loop with the required height clearance throughout an inboard length of the bonding wire, that is, a length of the bonding wire extending over the surface of the IC die, often leads to performance issues, such as decreased stability and inconsistency. This problem is particularly acute in cases where the inboard length of the bonding wire is greater than about 60% of the total length of the bonding wire.

In view of the foregoing, it would be desirable to have a method of forming a stable and consistent wire loop with an appropriate height clearance throughout its inboard length to prevent wire-to-die shorting.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a conventional integrated circuit (IC) device;

FIG. 2 is an enlarged top plan view of an integrated circuit (IC) die attached to a lead frame in accordance with an embodiment of the present invention; and

FIG. 3 is an enlarged cross-sectional view of the IC die, the lead frame and the bonding wires of FIG. 2 encapsulated by a molding compound.

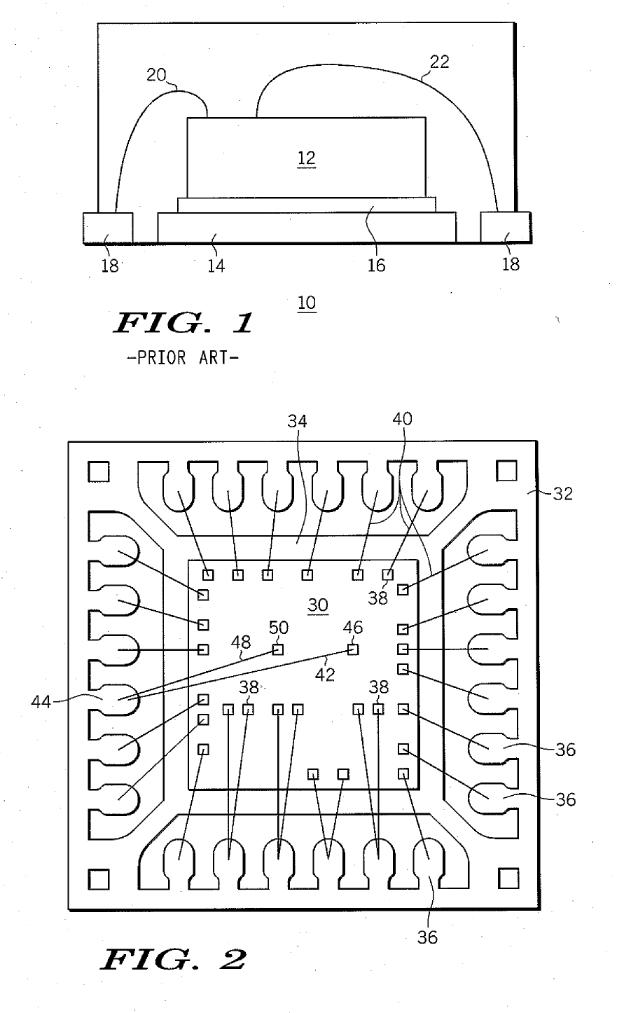

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

The present invention provides a method of connecting a lead frame lead finger to a bond pad on an integrated circuit (IC) die. The method includes the step of bonding a first bonding wire from the lead finger to an intermediate point. A second bonding wire is bonded from the lead finger to the bond pad such that the first bonding wire supports the second bonding wire.

The present invention also provides a semiconductor package including a lead frame having a die support area and a plurality of lead fingers located around the die support area. An integrated circuit (IC) die having a plurality of bond pads is attached to the die support area. Respective lead fingers are connected to respective bond pads with respective bonding wires: a first bonding wire connects a first lead finger to an intermediate point; and a second bonding wire connects the first lead finger to a first bond pad such that the first bonding wire supports the second bonding wire.

The present invention further provides a method of making a semiconductor package including the step of attaching an integrated circuit (IC) die having a plurality of bond pads to a die support area of a lead frame having a plurality of lead fingers located around the die support area. Respective lead fingers are connected to respective bond pads with respective bonding wires: a first bonding wire connects a first lead finger to an intermediate point; and a second bonding wire connects the first lead finger to a first bond pad such that the first bonding wire supports the second bonding wire. The lead frame, the IC die and the bonding wires are encapsulated with a molding compound.

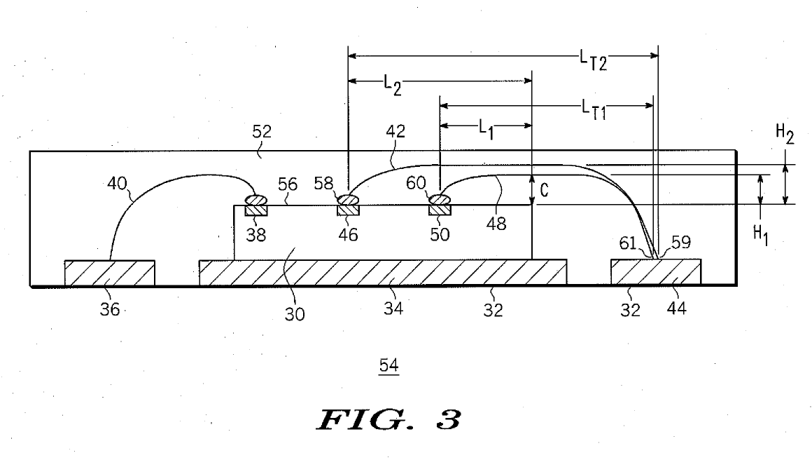

Referring now to FIG. 2, an enlarged top plan view of an integrated circuit (IC) die 30 attached to a lead frame 32 is shown. The IC die 30 may be a processor, such as a digital signal processor (DSP), a special function circuit, such as a memory address generator, or a circuit that performs any other type of function. The IC die 30 is not limited to a particular technology such as CMOS, or derived from any particular wafer technology. Further, the present invention can accommodate various die sizes, as will be understood by those of skill in the art. A typical example is a memory die having a size of about 15 mm by 15 mm. The lead frame 32 includes a die support area 34 and a plurality of lead fingers 36 located around the die support area 34. The IC die 30 is attached to the die support area 34 of the lead frame 32. The IC die 30 may be attached to the die support area 34 in a variety of ways, as known by those of skill in the art, such as with glue or an adhesive material placed on a back surface of the IC die 30, or with an adhesive tape.

The IC die 30 includes a plurality of bond pads 38, each of which is connected to respective ones of the lead fingers 36 with respective ones of a plurality of bonding wires 40. While it is typical for one lead finger to connect to one bond pad, as can be seen, sometimes one lead finger is connected to more than one bond pad. Many of the bond pads 38 are located along a periphery of the IC die 30. However, as shown in FIG. 2, some of the bond pads 38 are located in a central area of the IC die 30. Thus, various lengths of the bonding wires 40 are required because the distance from the lead fingers 36 to the bond pads 38 is not uniform. Indeed, some of the bond wires 40 must be very long to extend from a lead finger 36 to a bond pad 38 in a central area of the IC die 30.

The bonding wires 40 may be made of gold (Au), copper (Cu), aluminium (Al) or other electrically conductive materials as are known in the art and commercially available. The layout of the bond pads 38 on the IC die 30 and the arrangement of the bonding wires 40 in FIG. 2 are merely exemplary; those of skill in the art will understand that the present invention is not limited by the layout of the bond pads 38 or by the arrangement of the bonding wires 40.

Referring again to FIG. 2, a long wire 42 extends from a lead finger 44 to connect the lead finger 44 to a centrally located bond pad 46. In order to prevent the long wire 42 from drooping and possibly contacting a surface of the IC die 30, a shorter wire 48 extends from the lead finger 44 to an intermediate point 50. The longer wire 42 rests on or contacts the shorter wire 48 such that the shorter wire 48 acts as a support for the longer wire 42 and prevents the long wire 42 from sagging or drooping and contacting the IC die 30.

Referring now to FIG. 3, an enlarged cross-sectional view of the IC die 30, the lead frame 32 and the bonding wires 40 of FIG. 2 is shown. The IC die 30, the bonding wires 40 and at least a top portion of the lead frame 32 are encapsulated by a molding compound 52 to form a semiconductor package 54. A molding operation such as, for example, an injection molding process may be used to perform the encapsulation. The molding compound 52 may comprise well-known commercially available molding materials such as plastic or epoxy. The semiconductor package 54 may be any type of wire-bonded package such as, for example, BGA, QFN, QFP, PLCC, CUEBGA, TBGA, and TSOP.

As shown in FIG. 3, the long bonding wire 42 is longer in length than the short bonding wire 48. The shorter, more stable, bonding wire 48 acts as a brace for the long bonding wire 42, providing support to the long bonding wire 42 and preventing the long bonding wire 42 from touching a surface 56 of the IC die 30. The short bonding wire 48 has an inboard length of L₁ and the long bonding wire 42 has an inboard length of L₂.

With the support provided by the short bonding wire 48, the long bonding wire 42 has a stable and consistent wire loop with an appropriate height clearance C throughout its inboard length L₂ to prevent wire-to-die shorting. In this particular embodiment, an inboard length L₁ of the short bonding wire 48, that is, a length of the short bonding wire 48 extending over the surface 56 of the IC die 30, is less than about 55% of a total length L_{T1} of the short bonding wire 48, while an inboard length L₂ of the long bonding wire 42, that is, a length of the long bonding wire 42 extending over the surface 56 of the IC die 30, is greater than about 65% of a total length L_{T2} of the long bonding wire 42.

In one embodiment, each of the long and short bonding wires 42 and 48 has a diameter of about 1.3 mil, lengths L_{T1} and L_{T2} of about 63.7 and about 88.5 mil, respectively, and loop heights H₁ and H₂ of about 6.5˜7.5 mil and about 8.5˜9.5 mil, respectively. Although specific and relative dimensions of the long and short bonding wires 42 and 48 are described herein, those of skill in the art will understand that the present invention is not limited to the described dimensions.

First ends 58 and 60 of the long and short bonding wires 42 and 48 are bonded to the centrally located bond pad 46 and the intermediate point 50, respectively, while second ends 59 and 61 of the long and short bonding wires 42 and 48 are bonded to the lead finger 44. As can be seen, the bonding wires 40 in this particular embodiment are bonded to the bond pads 38 of the IC die 30 and the lead fingers 36 by ball bonding. Nevertheless, those of skill in art will understand that the present invention is not limited to any single wire bonding technique. In the described embodiment, the intermediate point 50 is a bond pad. However, it should be understood that the present invention is not limited to bonding the first end 60 of the short bonding wire 48 to a bond pad. Further, in this particular embodiment, the respective second ends 59 and 61 of the long and short bonding wires 42 and 48 are bonded to nearby spots on the lead finger 44; in an alternative embodiment, the respective second ends 59 and 61 of the long and short bonding wires 42 and 48 are bonded to the same spot on the lead finger 44. It would also be possible to bond the long and short bond wires 42 and 48 to different ones of the lead fingers 44.

As is evident from the foregoing discussion, the present invention provides a method of forming a stable and consistent wire loop by providing a brace in the form of a shorter, and therefore inherently more stable, wire loop to support the longer wire loop. The shorter wire loop also prevents the longer wire loop from contacting a surface of an IC die.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A method of connecting a lead frame lead finger to a bond pad on an integrated circuit (IC) die, comprising:
bonding a first bonding wire from the lead finger to an intermediate point; and
bonding a second bonding wire from the lead finger to the bond pad, wherein the first bonding wire supports the second bonding wire.

2. The method of connecting a lead frame lead finger to a bond pad on an IC die of claim 1, wherein the first bonding wire prevents the second bonding wire from touching a surface of the IC die.

3. The method of connecting a lead frame lead finger to a bond pad on an IC die of claim 1, wherein the intermediate point is a second bond pad.

4. The method of connecting a lead frame lead finger to a bond pad on an IC die of claim 3, wherein the second bond pad is located along a periphery of the IC die.

5. The method of connecting a lead frame lead finger to a bond pad on an IC die of claim 1, wherein an inboard length of the second bonding wire is greater than about 65% of a total length of the second bonding wire.

6. The method of connecting a lead frame lead finger to a bond pad on an IC die of claim 5, wherein an inboard length of the first bonding wire is less than about 55% of a total length of the first bonding wire.

7. The method of connecting a lead frame lead finger to a bond pad on an IC die of claim 1, wherein the second bonding wire has a loop height of about 8.5˜9.5 mil.

8. The method of connecting a lead frame lead finger to a bond pad on an IC die of claim 7, wherein the first bonding wire has a loop height of about 6.5˜7.5 mil.

9. The method of connecting a lead frame lead finger to a bond pad on an IC die of claim 1, wherein the second bonding wire has a length of greater than about 80 mil.

10. The method of connecting a lead frame lead finger to a bond pad on an IC die of claim 9, wherein the first bonding wire has a length of less than about 60 mil.

11. A method of making a semiconductor package, comprising:
attaching an integrated circuit (IC) die having a plurality of bond pads to a die support area of a lead frame having a plurality of lead fingers located around the die support area;
connecting respective lead fingers to respective bond pads with respective bonding wires, wherein a first bonding wire connects a first lead finger to an intermediate point and a second bonding wire connects the first lead finger to a first bond pad, and wherein the first bonding wire supports the second bonding wire; and
encapsulating the IC die, the bonding wires, and at least a portion of the lead frame with a molding compound.

12. The method of making a semiconductor package of claim 11, wherein the intermediate point is a bond pad located along a periphery of the IC die.

13. A semiconductor package, comprising:
a lead frame having a die support area and a plurality of lead fingers located around the die support area;
an integrated circuit (IC) die having a plurality of bond pads, wherein the IC die is attached to the lead frame die support area; and
respective bonding wires connecting respective lead fingers to respective bond pads, wherein a first bonding wire connects a first lead finger to an intermediate point and a second bonding wire connects the first lead finger to a first bond pad, and wherein the first bonding wire supports the second bonding wire.

14. The semiconductor package of claim 13, wherein the first bonding wire prevents the second bonding wire from touching a surface of the IC die.

15. The semiconductor package of claim 14, wherein an inboard length of the second bonding wire is greater than about 65% of a total length of the second bonding wire.

16. The semiconductor package of claim 13, wherein an inboard length of the first bonding wire is less than about 55% of a total length of the first bonding wire.

17. The semiconductor package of claim 13, wherein the second bonding wire has a loop height of about 8.5˜9.5_mil.

18. The semiconductor package of claim 17, wherein the first bonding wire has a loop height of about 6.5˜7.5_mil.
